(19) United States
(12) Patent Application Publication
(10) Pub. No.: US 2026/0344114 A1
(43) Pub. Date: Oct. 29, 2026

(54) WHITE LED LIGHT SOURCE MODULE WITH HIGH COLOR GAMUT

(71) Applicant: Micro Nano Photonics (Shenzhen) Co., LTD, Shenzhen (CN)

(72) Inventor: ERCHENG LI, Shenzhen (CN)

(21) Appl. No.: 19/193,278

(22) Filed: Apr. 29, 2025

(51) Int. Cl. H10H 20/811; H10H 20/813; H10H 20/851

(52) U.S. Cl. CPC H10H 20/811; H10H 20/8131; H10H 20/8512

(57) ABSTRACT

Disclosed is a white LED light source module with a high color gamut. The white LED light source module with a high color gamut includes an LED chip and a light-emitting element; a mixed spectral output of the LED chip is cyan light with a peak wavelength of 440-560 nm; a mixed spectral output of the light-emitting element is red light or yellow-green light, with a peak wavelength of 520-650 nm; the LED chip includes a first quantum well layer and a second quantum well layer, where a difference between a peak wavelength of the first quantum well layer and a peak wavelength of the second quantum well layer is greater than 60 nm; the first quantum well layer is electroluminescent, and the second quantum well layer is photoluminescent; and the light-emitting element is photoluminescent.

### TECHNICAL FIELD

The present disclosure relates to the field of semiconductor lighting, and in particular to a white LED light source module with a high color gamut.

### BACKGROUND

Color gamut is an indicator used to measure a display's capability to accurately reproduce colors, and a wider color gamut indicates richer color representation.

In the prior art, panel technology and backlight technology are mainly employed to enhance the color gamut. In the backlight technology, the color gamut is enhanced mainly through the following three technical solutions:
1. Blue LED light source+quantum dot film, described in Chinese Patent Application No. CN201480005245.1 titled “Quantum Dot Film”;
2. White LED+quantum dot diffusion plate, described in Chinese Patent Application No. CN202110840289.8 titled “Quantum Dot Diffusion Plate and Preparation Method Therefor”; and
3. RGB Mini-LED as a backlight source, described in Chinese Patent Application No. CN202111382153.3 titled “RGB Mini-LED Field Sequence Backlight Control System and Method”.

None of the above three technical solutions enables to simultaneously balance core indicators of a high color gamut, a low cost, high reliability, color stability, and the like.

### SUMMARY

An objective of examples of the present disclosure is to solve the technical problems of limitations in color gamut performance of displays, including failure to achieve a high color gamut, a low cost, high reliability, and color stability simultaneously.

In order to solve the above problems, a white LED light source module with a high color gamut is disclosed in an example of the present disclosure. The white LED light source module with a high color gamut is a white LED light source simultaneously characterized by the high color gamut, the low cost, the high reliability, and the high color stability.

The present disclosure provides a white LED light source module with a high color gamut, and the white LED light source module with a high color gamut includes an LED chip and a light-emitting element; a mixed spectral output of the LED chip is cyan light, and a peak wavelength of the cyan light falls within a range of 440-560 nm; a cyan light spectrum includes a blue light spectrum and a green light spectrum, a peak wavelength of the blue light spectrum falls within a range of 440-480 nm, and a peak wavelength of the green light spectrum falls within a range of 500-560 nm; a mixed spectral output of the light-emitting element is red light or yellow-green light, with a peak wavelength of 520-650 nm; the LED chip includes a first quantum well layer and a second quantum well layer, where a difference between a peak wavelength of the first quantum well layer and a peak wavelength of the second quantum well layer is greater than 60 nm; the first quantum well layer is electroluminescent, and the second quantum well layer is photoluminescent; and the light-emitting element is photoluminescent.

According to a further technical solution, a CIE-1931 chromaticity coordinate X of a mixed spectral output of the LED chip falls within a range of 0.1-0.2, and a CIE-1931 chromaticity coordinate Y of the mixed spectral output of the LED chip falls within a range of 0.15-0.3.

According to a further technical solution, a spectral output of the first quantum well layer is blue light, a peak wavelength falls within a range of 400 nm-480 nm, a half-wave width of wavelength in a spectral range is equal to or less than 40 nm, the CIE-1931 chromaticity coordinate X falls within a range of 0.1-0.2, and the CIE-1931 chromaticity coordinate Y falls within a range of 0.01-0.15.

According to a further technical solution, a spectral output of the second quantum well layer is green light, a peak wavelength falls within a range of 500-560 nm, a half-wave width of wavelength in a spectral range is equal to or less than 40 nm, the CIE-1931 chromaticity coordinate X falls within a range of 0.15-0.3, and the CIE-1931 chromaticity coordinate Y falls within a range of 0.6-0.8.

According to a further technical solution, the light-emitting element includes red powder and a transparent adhesive, where the red powder is photoluminescent, and a refractive index of the transparent adhesive falls within a range of 1.3-1.8; and a peak luminous intensity of red light from the red powder is greater than or equal to a peak luminous intensity of green light from the LED chip.

According to a further technical solution, a peak wavelength of the red powder falls within a range of 600-660 nm, and a half-wave width of wavelength in a spectral range is equal to or less than 70 nm.

According to a further technical solution, the light-emitting element further includes green powder, and the green powder is photoluminescent.

According to a further technical solution, a peak wavelength of the green powder falls within a range of 500-560 nm, and a half-wave width of wavelength in a spectral range is equal to or less than 70 nm.

According to a further technical solution, the light-emitting element is located above the first quantum well layer, the second quantum well layer is located below the first quantum well layer, and a peak luminous intensity of the first quantum well layer is greater than a peak luminous intensity of the second quantum well layer.

Compared with the prior art, the present disclosure achieves the technical effects as follows:

A light-emitting layer of the white LED light source module with a high color gamut requires only two quantum well layers, thereby minimizing costs; and only one quantum well layer is electroluminescent, such that reliability is high.

### BRIEF DESCRIPTION OF DRAWINGS

To describe the technical solutions in the examples of the present disclosure more clearly, the accompanying drawings required for describing the examples are briefly described below. Apparently, the accompanying drawings in the following description show some examples of the present disclosure, and those of ordinary skill in the art may still derive other drawings from these accompanying drawings without creative efforts.

FIG. 1 is a schematic structural diagram of a LED light source module with a high color gamut provided by the present disclosure.

FIG. 2 is a schematic structural diagram of a LED chip provided by the present disclosure.

### REFERENCE NUMERALS IN FIGURES

1—LED Chip; 2—light—emitting element;
11—first quantum well layer; 12—second quantum well layer;
21—red powder; and 22—green powder.

### DESCRIPTION OF EMBODIMENTS

The technical solutions in the examples will be clearly and completely described below with reference to the accompanying drawings in the examples of the present disclosures, and similar reference numerals marked in the accompanying drawings denote similar assemblies. Apparently, the examples described below are merely some examples rather than all examples of the present disclosure. Based on the described examples of the present disclosure, all other examples acquired by those of ordinary skill in the art without making creative efforts fall within the protection scope of the present disclosure.

It is to be understood that the terms “including” and “comprising” used in the specification and the appended claims refer to the existence of described features, integers, steps, operations, elements and/or assemblies, but do not exclude the existence or addition of one or more other features, entireties, steps, operations, elements, assemblies and/or their combinations.

It is also to be understood that the terms used in the specification of examples of the present disclosure are merely for the purpose of describing specific examples and are not intended to limit examples of the present disclosure. As used in the specification of examples and the appended claims of the present disclosure, the singular terms “a”, “an” and “the” are intended to include the plural forms unless clearly indicated otherwise in the context.

To facilitate understanding of the technical solutions provided in the present disclosure, the research background of the technical solutions in the present disclosure is briefly outlined below: A LED chip 1 includes a substrate (also referred to as a base layer), an n-type semiconductor layer, an active layer (also known as a light-emitting layer), and a p-type semiconductor layer. Optical primary colors include: red, green, and blue (RGB). The optical primary colors are mixed to form display colors, all the three primary colors are mixed simultaneously to produce white, and white is one of colors in an achromatic color system (black, white, and gray).

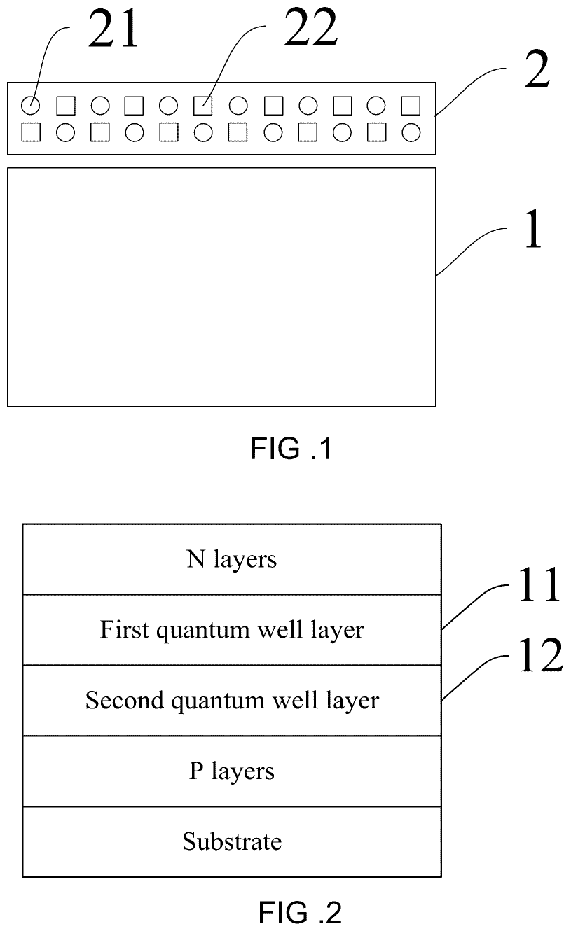

With reference to FIGS. 1-2, a white LED light source module with a high color gamut is provided in an example of the present disclosure. The white LED light source module with a high color gamut includes an LED chip 1 and a light-emitting element 2; a mixed spectral output of the LED chip 1 is cyan light, and a peak wavelength of the cyan light falls within a range of 440-560 nm; a cyan light spectrum includes a blue light spectrum and a green light spectrum, a peak wavelength of the blue light spectrum falls within a range of 440-480 nm, and a peak wavelength of the green light spectrum falls within a range of 500-560 nm; a mixed spectral output of the light-emitting element 2 is red light or yellow-green light, with a peak wavelength of 520-650 nm; the LED chip 1 includes a first quantum well layer 11 and a second quantum well layer 12, where a difference between a peak wavelength of the first quantum well layer 11 and a peak wavelength of the second quantum well layer 12 is greater than 60 nm; the first quantum well layer 11 is electroluminescent, and the second quantum well layer 12 is photoluminescent; and the light-emitting element 2 is photoluminescent. Various components are described in detail as follows:

In this example, both the first quantum well layer 11 and the second quantum well layer 12 are active layers of the LED chip 1, the first quantum well layer 11 and the second quantum well layer 12 are distributed in a laminated manner, the first quantum well layer 11 is located above the second quantum well layer 12, or the first quantum well layer 11 located below the second quantum well layer 12, and it is understood that sequential or vertical arrangement of the first quantum well layer 11 and the second quantum well layer 12 is not limited. A structure of the LED chip 1 includes a face-up structure, a flip-chip structure, a vertical structure, and any other structure derived from the above structures, such as a thin-film chip structure. A side length of the LED chip 1 falls within a range of 5-3000 μm. The LED chip 1 does not require phosphor excitation and emits two colors of light spectra simultaneously upon electrification, and cyan light is formed after mixing, where the first color of light is blue light and the second color of light is green light. The light-emitting element 2 emits red light after stimulation by light emitted from the LED chip 1, and white light is obtained after mixing of blue light, green light, and red light.

In an example, a peak wavelength of a blue light spectrum of the LED chip 1 falls within a range of 440-480 nm, a peak wavelength of a green light spectrum of the LED chip 1 falls within a range of 500-560 nm, a cyan light spectrum is obtained after combining the blue light spectrum and the green light spectrum of the LED chip 1, and a peak wavelength of the cyan light spectrum falls within a range of 440-560 nm. A difference between the peak wavelength of the blue light spectrum and the peak wavelength of the green light spectrum is greater than 60 nm. Cyan light is formed after mixing blue light and green light. The first quantum well layer 11 includes a nitride compound semiconductor represented by a chemical formula IniGajAlkN, where 0≤i, 0≤j, 0≤k, and i+j+k=1. The second quantum well layer 12 of the LED chip 1 is a compound semiconductor composed of nitride or phosphide.

Examples of the present disclosure achieve the technical effects as follows:

A light-emitting layer of the white LED light source module with a high color gamut requires only two quantum well layers, thereby minimizing costs; and only one quantum well layer is electroluminescent, which exhibits no significant color drift and high color consistency.

With reference to FIGS. 1-2 again, in this example, a CIE-1931 chromaticity coordinate X of a mixed spectral output of the LED chip 1 falls within a range of 0.1-0.2, and a CIE-1931 chromaticity coordinate Y of the mixed spectral output of the LED chip 1 falls within a range of 0.15-0.3.

In this example, a spectral output of the LED chip 1 is cyan light, the CIE-1931 chromaticity coordinate X falls within a range of 0.13-0.18, and the CIE-1931 chromaticity coordinate Y falls within a range of 0.15-0.25.

Further, a spectral output of the first quantum well layer 11 is blue light, a peak wavelength falls within a range of 400 nm-480 nm, a half-wave width of wavelength in a spectral range is equal to or less than 40 nm, the CIE-1931 chromaticity coordinate X falls within a range of 0.1-0.2, and the CIE-1931 chromaticity coordinate Y falls within a range of 0.01-0.15.

Further, a spectral output of the second quantum well layer 12 is green light, a peak wavelength falls within a range of 500-560 nm, a half-wave width of wavelength in a spectral range is equal to or less than 40 nm, the CIE-1931 chromaticity coordinate X falls within a range of 0.15-0.3, and the CIE-1931 chromaticity coordinate Y falls within a range of 0.6-0.8.

Further, the light-emitting element 2 includes red powder 21 and a transparent adhesive, where the red powder 21 is photoluminescent, and a refractive index of the transparent adhesive falls within a range of 1.3-1.8; and a peak luminous intensity of red light from the red powder 21 is greater than or equal to a peak luminous intensity of green light from the LED chip 1.

Specifically, the red powder 21 includes a red quantum dot phosphor and red base powder. When the red powder 21 is excited by an LED light source, a spectral output is red light with a peak wavelength of 600-660 nm; and a half-width wavelength thereof does not exceed 70 nm. The transparent adhesive includes but is not limited to a silicone-based adhesive (derived from a siloxane polymer), a resin-based adhesive (such as acrylic resin, polyurethane resin, or the like), and an epoxy adhesive (derived from an epoxy resin system), and a refractive index of the transparent adhesive falls within a range of 1.3-1.8.

In this example, the light-emitting element 2 is formed by uniformly mixing the red powder 21 and the transparent adhesive, where a peak luminous intensity of red light emitted from the red powder 21 is denoted as Ered, a peak luminous intensity of green light emitted from the LED chip 1 is denoted as Egreen, and it is understood that Ered≥Egreen.

The red base powder includes but is not limited to nitride phosphors (e.g., BaSi2O2N2, α-Sialon, β-Sialon, Sr2Si5N8, and CaAlSiN3), and fluoride phosphors (e.g., K2SiF6:Mn4+, K2GeF6:Mn4+, and K2TiF6:Mn4+). The red base powder is composed of one or more of the above materials with a particle diameter range of 1-50 μm, and is photoluminescent and excited by the LED light source, and a spectral output is red light with a peak wavelength of 600-660 nm after excitation.

The red quantum dot phosphor includes but is not limited to cadmium selenide (CdSe), indium phosphide (InP), and perovskite (ABX3). The red quantum dot phosphor is composed of one or more of the above materials with a particle diameter range of 10-30 nm, and is photoluminescent and excited by the LED light source, a spectral output is red light with a peak wavelength of 600-660 nm, and a half-width wavelength thereof does not exceed 50 nm.

Further, a peak wavelength of the red powder 21 falls within a range of 600-660 nm, and a half-wave width of wavelength in a spectral range is equal to or less than 70 nm.

Specifically, when the red powder 21 is excited by an LED light source, a spectral output is red light with a peak wavelength of 600-660 nm after excitation; and a half-width wavelength thereof does not exceed 70 nm. In an example, a peak luminous intensity of red light emitted from the red powder 21 is greater than or equal to a peak luminous intensity of green light emitted from the LED chip 1.

Further, the light-emitting element 2 further includes green powder 22, and the green powder 22 is photoluminescent.

Specifically, the green powder 22 includes green base powder and a green quantum dot phosphor. When the green powder 22 is excited by an LED light source, a spectral output is green light with a peak wavelength of 500-560 nm after excitation; and a half-width wavelength thereof does not exceed 70 nm.

In this example, the peak luminous intensity of red light from the red powder 21 is greater than or equal to a sum of peak luminous intensities of green light from the LED chip 1 and the green powder 22; and the sum of peak luminous intensities of green light from the LED chip 1 and the green powder 22 is less than or equal to a peak luminous intensities of blue light from the LED chip 1, the light-emitting element 2 is formed by uniformly mixing the red powder 21, the green powder 22, and the transparent adhesive, where the light-emitting element 2 emits yellow-green light, the peak luminous intensity of red light emitted from the red powder 21 is denoted as Ered, a sum of peak luminous intensities of green light emitted from the LED chip 1 and the green powder 22 is denoted as Egreen_total, a peak luminous intensity of blue light from the LED chip 1 is denoted as Eblue, and it is understood that Ered≥Egreen_total and Eblue≥Egreen_total.

The green base powder includes but is not limited to a sialon ceramic phosphor (β-SiAlON), a silicate phosphor (Ba2SiO4, and Sr3SiO5), and an aluminate phosphor (YAG, (Gd, Y) AG, (Lu, Y) AG). The green base powder is composed of one or more of the above materials with a particle diameter range of 1-50 μm, and is photoluminescent and excited by the LED light source, and a peak wavelength thereof after excitation falls within a range of 500-560 nm.

Further, a peak wavelength of the green powder 22 falls within a range of 500-560 nm, and a half-wave width of wavelength in a spectral range is equal to or less than 70 nm.

Specifically, when the green powder 22 is excited by light emitted from the LED chip 1, a peak wavelength of a spectral output is 500-560 nm after excitation; and a half-width wavelength thereof does not exceed 70 nm.

Further, the light-emitting element 2 is located above the first quantum well layer 11, and the second quantum well layer 12 is located below the first quantum well layer 11.

In this example, a peak luminous intensity of blue light emitted from the first quantum well layer 11 is 2-5 times a peak luminous intensity of green light emitted from the second quantum well layer 12, the light-emitting element 2 is located above the first quantum well layer 11, and the second quantum well layer 12 is located below the first quantum well layer 11. Both the light-emitting element 2 and the second quantum well layer 12 are photoluminescent, the first quantum well layer 11 with a higher peak luminous intensity is arranged between the light-emitting element 2 and the second quantum well layer 12 with a lower peak luminous intensity, and the first quantum well layer 11 effectively excites both the light-emitting element 2 and the second quantum well layer 12 to emit light.

In the above examples, each example is described with its own emphasis. For parts that are not described in detail in a certain example, please refer to the relevant descriptions of other examples.

In the description of the present disclosure, it should be understood that the terms “center”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, etc. indicate azimuthal or positional relations based on those shown in the accompanying drawings only for ease of description of the present disclosure and for simplicity of description, and are not intended to indicate or imply that the referenced device or element must have a particular orientation and be constructed and operative in a particular orientation, and thus may not be interpreted as a limitation on the present disclosure.

Furthermore, the terms “first” and “second” are merely for the purpose of description, and cannot be construed as indicating or implying relative importance or implicitly specifying the number of technical features indicated. Thus, a feature defined with “first” and “second” may explicitly or implicitly include one or more of the features. In the description of the present disclosure, “a plurality of” means two or more, unless expressly specified otherwise.

In the present disclosure, it is to be noted that, unless otherwise explicitly specified and defined, the terms “mounting”, “connecting”, “connection”, “fixing”, etc. should be understood in a broad sense. For example, the connection may be a fixed connection, a detachable connection or an integral connection; may be a mechanical connection or an electrical connection; may be a direct connection or an indirect connection by using an intermediate medium; or may be intercommunication between two components, or an interactive relation between two elements. The specific meanings of the above terms in the present disclosure may be understood on a case-by-case basis for those of ordinary skill in the art.

In the present disclosure, unless otherwise expressly stated and defined, a first feature being “above” or “below” a second feature may include the first and second features being in direct contact or that the first and second features being not in direct contact but being in contact by means of additional features between the first and second features. In addition, the first feature being “over”, “above” and “on the top of” the second feature includes that the first feature is over and above the second feature, or simply means that the level of the first feature is higher than that of the second feature. The first feature being “under”, “below” and “at the bottom of” the second feature includes that the first feature is under and below the second feature, or simply means that the level of the first feature is lower than that of the second feature.

In the description of the present specification, the description of reference terms such as “one example”, “some examples”, “example”, “specific example” or “some examples” means that specific features, structures, materials or characteristics described in combination with the example or embodiment are included in at least one example or example of the present disclosure. In the present description, the schematic description of the above terms is not to be construed as necessarily referring to the same example or embodiment. Moreover, the specific features, structures, materials or characteristics described may be combined in a suitable manner in any one or more examples or embodiments. Further, those skilled in the art may integrate and combine different examples or embodiments described in the present specification.

It is apparent that those skilled in the art may perform various changes and modifications on the present disclosure without departing from the spirit and scope of the present disclosure. Therefore, if these changes and modifications on the present disclosure fall within the scope of the claims of the present disclosure and their equivalent technologies, the present disclosure is also intended to include these changes and modifications.

The foregoing descriptions are merely specific implementations of the present disclosure, and are not intended to limit the protection scope of the present disclosure. Various equivalent modifications or substitutions made by a person skilled in the art easily within the technical scope disclosed in the present disclosure shall fall within the protection scope of the present disclosure. Therefore, the protection scope of the present disclosure should be subject to a protection scope of the claims.

What is claimed is:

1. A white LED light source module with a high color gamut, comprising an LED chip and a light-emitting element;
a mixed spectral output of the LED chip is cyan light, and a peak wavelength of the cyan light falls within a range of 440-560 nm; a cyan light spectrum comprises a blue light spectrum and a green light spectrum, a peak wavelength of the blue light spectrum falls within a range of 440-480 nm, and a peak wavelength of the green light spectrum falls within a range of 500-560 nm;
a mixed spectral output of the light-emitting element is red light or yellow-green light, with a peak wavelength of 520-650 nm;
the LED chip comprises a first quantum well layer and a second quantum well layer, wherein a difference between a peak wavelength of the first quantum well layer and a peak wavelength of the second quantum well layer is greater than 60 nm; and
the first quantum well layer is electroluminescent, and the second quantum well layer is photoluminescent; and the light-emitting element is photoluminescent.

2. The white LED light source module with a high color gamut according to claim 1, wherein a CIE-1931 chromaticity coordinate X of a mixed spectral output of the LED chip falls within a range of 0.1-0.2, and a CIE-1931 chromaticity coordinate Y of the mixed spectral output of the LED chip falls within a range of 0.15-0.3.

3. The white LED light source module with a high color gamut according to claim 2, wherein a spectral output of the first quantum well layer is blue light, a peak wavelength falls within a range of 400 nm-480 nm, a half-wave width of wavelength in a spectral range is equal to or less than 40 nm, the CIE-1931 chromaticity coordinate X falls within a range of 0.1-0.2, and the CIE-1931 chromaticity coordinate Y falls within a range of 0.01-0.15.

4. The white LED light source module with a high color gamut according to claim 2, wherein a spectral output of the second quantum well layer is green light, a peak wavelength falls within a range of 500-560 nm, a half-wave width of wavelength in a spectral range is equal to or less than 40 nm, the CIE-1931 chromaticity coordinate X falls within a range of 0.15-0.3, and the CIE-1931 chromaticity coordinate Y falls within a range of 0.6-0.8.

5. The white LED light source module with a high color gamut according to claim 2, wherein the light-emitting element comprises red powder and a transparent adhesive, wherein the red powder is photoluminescent, and a refractive index of the transparent adhesive falls within a range of 1.3-1.8; and a peak luminous intensity of red light from the red powder is greater than or equal to a peak luminous intensity of green light from the LED chip.

6. The white LED light source module with a high color gamut according to claim 5, wherein a peak wavelength of the red powder falls within a range of 600-660 nm, and a half-wave width of wavelength in a spectral range is equal to or less than 70 nm.

7. The white LED light source module with a high color gamut according to claim 5, wherein the light-emitting element further comprises green powder, and the green powder is photoluminescent.

8. The white LED light source module with a high color gamut according to claim 7, wherein a peak wavelength of the green powder falls within a range of 500-560 nm, and a half-wave width of wavelength in a spectral range is equal to or less than 70 nm.

9. The white LED light source module with a high color gamut according to claim 1, wherein the light-emitting element is located above the first quantum well layer, the second quantum well layer is located below the first quantum well layer, and a peak luminous intensity of the first quantum well layer is greater than a peak luminous intensity of the second quantum well layer.
